(19) United States
(12) Patent Application Publication
(10) Pub. No.: US 2026/0305415 A1
(43) Pub. Date: Oct. 1, 2026

(54) WIRING SUBSTRATE AND SEMICONDUCTOR DEVICE

(71) Applicant: Shinko Electric Industries Co., LTD., Nagano-shi (JP)

(72) Inventors: Yuna Kamioka, Nagano-shi (JP); Tomoyuki Shimodaira, Nagano-shi (JP); Kotaro Kodani, Nagano-shi (JP)

(73) Assignee: Shinko Electric Industries Co., LTD., Nagano-shi (JP)

(21) Appl. No.: 19/573,905

(22) Filed: Mar. 20, 2026

(30) Foreign Application Priority Data
Mar. 25, 2025 (JP) 2025-050660

(51) Int. Cl. H10W 70/652; H10W 70/65; H10W 70/68

(52) U.S. Cl. CPC H10W 70/652; H10W 70/6565; H10W 70/68

(57) ABSTRACT

A wiring substrate includes an insulation layer, a recess recessed from an upper surface of the insulation layer, a connection pad arranged in the recess, an adhesion-promoting film arranged between part of a side surface of the connection pad and part of a wall surface of the recess so that the side surface includes a covered surface covered by the adhesion-promoting film and an exposed surface exposed from the adhesion-promoting film, a first gap defined between the exposed surface and the wall surface, a connection terminal covering an upper surface of the connection pad and filling the first gap, and a wiring layer arranged on a lower surface of the insulation layer and electrically connected to the connection pad. The exposed surface is arranged above the covered surface and is inclined to approach a planar center of the connection pad toward the upper surface of the connection pad.

### CROSS-REFERENCE TO RELATED APPLICATIONS

This application is based upon and claims the benefit of priority from Japanese Patent Application No. 2025-050660, filed on Mar. 25, 2025, the entire contents of which are incorporated herein by reference.

### BACKGROUND

### 1. Field

The following description relates to a wiring substrate, a semiconductor device, and a method for manufacturing a wiring substrate.

### 2. Description of Related Art

Wiring substrates for mounting electronic components, such as semiconductor elements, are available in various shapes and structures. JP2024-92923A discloses an example of a typical wiring substrate. The wiring substrate includes an insulation layer having an upper surface including a recess, a connection pad arranged in the recess of the insulation layer and protruding upward beyond the upper surface of the insulation layer, and a connection terminal covering the connection pad. The connection terminal may be, for example, an external plating layer.

### SUMMARY

In the wiring substrate described above, it is desirable to improve the reliability of electrical connection between the connection pad and the connection terminal.

In one general aspect, a wiring substrate includes an insulation layer, a recess recessed downward from an upper surface of the insulation layer, a connection pad arranged in the recess, an adhesion-promoting film arranged between a portion of a side surface of the connection pad and a portion of a wall surface of the recess so that the side surface of the connection pad includes a covered surface covered by the adhesion-promoting film and an exposed surface exposed from the adhesion-promoting film, a first gap defined between the exposed surface of the connection pad and the wall surface of the recess, a connection terminal covering an upper surface of the connection pad and filling the first gap, and a wiring layer arranged on a lower surface of the insulation layer and electrically connected to the connection pad. The exposed surface is arranged above the covered surface. The exposed surface is inclined so as to approach a planar center of the connection pad as the exposed surface extends toward the upper surface of the connection pad.

Other features and aspects will be apparent from the following detailed description, the drawings, and the claims.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

### BRIEF DESCRIPTION OF THE DRAWINGS

FIG. 1 is a schematic cross-sectional view illustrating an embodiment of a wiring substrate.

FIG. 2 is an enlarged partial cross-sectional view of the wiring substrate illustrated in FIG. 1.

FIG. 3 is an enlarged partial cross-sectional view of the wiring substrate illustrated in FIG. 2.

FIG. 4 is a schematic cross-sectional view of a semiconductor device including the wiring substrate illustrated in FIG. 1.

FIGS. 5 and 6A are schematic cross-sectional views illustrating a method for manufacturing the wiring substrate of FIG. 1.

FIG. 6B is a schematic cross-sectional view enlarging the part surrounded by the single-dashed line illustrated in FIG. 6A.

FIGS. 7, 8, 9, 10, 11, 12, 13, 14, 15, 16, 17, 18, 19, 20, and 21A are schematic cross-sectional views illustrating a method for manufacturing the wiring substrate of FIG. 1.

FIG. 21B is a schematic cross-sectional view enlarging the part surrounded by the single-dashed line illustrated in FIG. 21A.

FIG. 22 is a schematic cross-sectional view illustrating a method for manufacturing the wiring substrate of FIG. 1.

FIG. 23 is an enlarged partial cross-sectional view illustrating a modified example of a wiring substrate.

FIG. 24 is an enlarged partial cross-sectional view illustrating another modified example of a wiring substrate.

FIG. 25 is an enlarged partial cross-sectional view illustrating another modified example of a wiring substrate.

Throughout the drawings and the detailed description, the same reference numerals refer to the same elements. The drawings may not be to scale, and the relative size, proportions, and depiction of elements in the drawings may be exaggerated for clarity, illustration, and convenience. To facilitate understanding, hatching lines may not be illustrated or may be replaced by shadings in the cross-sectional drawings.

### DETAILED DESCRIPTION

This description provides a comprehensive understanding of the methods, apparatuses, and/or systems described. Modifications and equivalents of the methods, apparatuses, and/or systems described are apparent to one of ordinary skill in the art. Sequences of operations are exemplary, and may be changed as apparent to one of ordinary skill in the art, with the exception of operations necessarily occurring in a certain order. Descriptions of functions and constructions that are well known to one of ordinary skill in the art may be omitted.

Exemplary embodiments may have different forms, and are not limited to the examples described. However, the examples described are thorough and complete, and convey the full scope of the disclosure to one of ordinary skill in the art.

In this specification, “at least one of A and B” should be understood to mean “only A, only B, or both A and B.”

An embodiment will now be described with reference to the accompanying drawings.

In this specification, “upward,” “downward,” and “sideward” directions refer to directions that allow for the reference characters denoting members to be read properly. In this specification, the terms “faced” and “facing” refer to a state in which surfaces or members are located in front of each other. The terms are not limited to a state in which the surfaces or members are located completely in front of each other and include a state in which the surfaces or members are located partially in front of each other. Moreover, the terms “faced” and “facing” will also be used to describe situations including a case in which two members are separated from each other and a case in which two members are in contact with each other. In the description of the present disclosure, a numerical range of “X1 to X2” defined by the lower limit value X1 and the upper limit value X2 refers to a range that is greater than or equal to X1 and less than or equal to X2, unless otherwise specified.

### Overall Structure of the Wiring Substrate 10

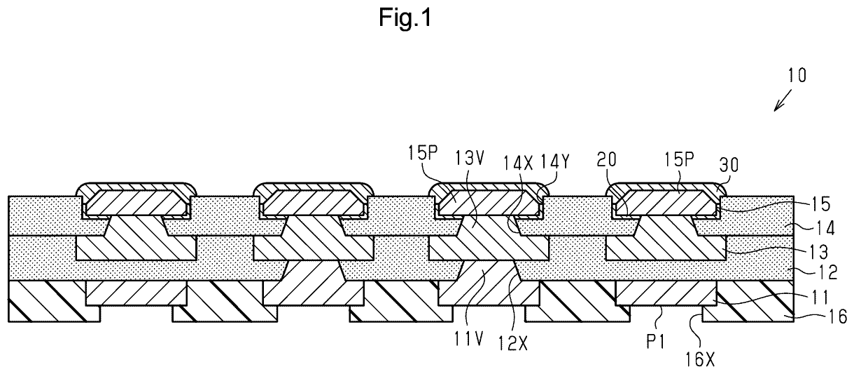

As illustrated in FIG. 1, a wiring substrate 10 has a structure in which a wiring layer 11, an insulation layer 12, a wiring layer 13, an insulation layer 14, and a wiring layer 15 are sequentially stacked. The wiring substrate 10 includes a solder resist layer 16 formed on the lower surface of the insulation layer 12. The wiring substrate 10 includes an adhesion-promoting film 20 arranged between the wiring layer 15 and the insulation layer 14. The wiring substrate 10 includes connection terminals 30 formed on the wiring layer 15. The wiring substrate 10 of the present embodiment differs from a wiring substrate manufactured through a typical build-up process. That is, the wiring substrate 10 differs from a wiring substrate formed by sequentially stacking a given number of build-up layers on both or one side of a core substrate serving as a support base. The wiring substrate 10 is a coreless substrate that does not include a support base.

In the present embodiment, with reference to FIG. 1, the side of the wiring substrate 10 at which the connection terminals 30 are arranged will be referred to as “the upper side” or “one side.” The side of the wiring substrate 10 at which the solder resist layer 16 is arranged will be referred to as “the lower side” or “the other side.” In the present embodiment, for the sake of convenience, a surface of a component located toward the connection terminals 30 will be referred to as “the upper surface” or “one surface” of the component. A surface of the component located toward the solder resist layer 16 will be referred to as “the lower surface” or “the other surface” of the component. The wiring substrate 10 may be used in a state reversed, upside down, or be arranged at any angle. In this specification, the term “plan view” refers to viewing an object from a direction normal to one surface of the wiring layer 15, unless otherwise specified. The term “planar shape” refers to a shape of an object as viewed from a direction normal to one surface of the wiring layer 15, unless otherwise specified.

The material of the wiring layers 11, 13, and 15 may be, for example, copper (Cu) or a copper alloy. The thickness of each of the wiring layers 11, 13, and 15 may be, for example, approximately 5 μm to 20 μm. The insulation layers 12 and 14 each include, for example, a non-photosensitive resin as a main component. The main component of the insulation layers 12 and 14 may be, for example, a thermosetting non-photosensitive resin, such as an epoxy resin, an imide resin, a phenol resin, a cyanate resin, or the like. The insulation layers 12 and 14 may include, for example, fillers such as silica or alumina. The thickness of the insulation layer 14 is set to be, for example, smaller than the thickness of the insulation layer 12. The thickness of the insulation layer 12 may be, for example, approximately 10 μm to 40 μm. The thickness of the insulation layer 14 may be, for example, approximately 2 μm to 20 μm. The solder resist layer 16 is, for example, an insulation layer including a photosensitive resin as a main component. The material of the solder resist layer 16 may be, for example, a photosensitive insulating resin including a phenol resin, a polyimide resin, or the like, as a main component. The solder resist layer 16 may include, for example, fillers such as silica or alumina.

The adhesion-promoting film 20 covers, for example, the side surface and the lower surface of the wiring layer 15. The adhesion-promoting film 20 is, for example, an organic film. The adhesion-promoting film 20 is formed from, for example, a material having two types of functional groups differing in reactivity in a single molecule. The material of the adhesion-promoting film 20 may be, for example, a silane coupling agent or a titanium coupling agent. The thickness of the adhesion-promoting film 20 may be, for example, approximately 10 nm to 200 nm.

Preferably, the silane coupling agent includes, as a functional group that is chemically bonded to an organic material such as resin, an amino group, an epoxy group, a mercapto group, an isocyanate group, a methacryloxy group, an acryloxy group, a ureido group, or a sulfide group. An optimal functional group is selected in accordance with the type of resin that is chemically bonded to the silane coupling agent.

Preferably, the silane coupling agent includes, as a functional group that is chemically bonded to an inorganic material such as metal, an azole group, a silanol group, a methoxy group, or an ethoxy group. An optimal functional group is selected in accordance with the type of metal that is chemically bonded to the silane coupling agent.

The wiring layer 13, the insulation layer 12, the wiring layer 11, and the solder resist layer 16 are sequentially stacked on the lower surface of the insulation layer 14. The wiring layer 15 is formed so that a portion of the wiring layer 15 is embedded in the insulation layer 14. The wiring layer 15 includes, for example, an upper portion protruding upward beyond the upper surface of the insulation layer 14. The wiring layer 15 includes connection pads 15P. The connection pads 15P serve as, for example, pads for connection with an electronic component such as a semiconductor element.

The insulation layer 14 is formed on the upper surface of the insulation layer 12. The insulation layer 14 covers the upper surface of the wiring layer 13. The insulation layer 14 surrounds each connection pad 15P. The insulation layer 14 covers the adhesion-promoting film 20, which covers the side surface and the lower surface of the connection pad 15P. Through holes 14X extend through the insulation layer 14 in the thickness direction to partially expose the lower surfaces of the connection pads 15P in given locations.

The wiring layer 13 is formed on the lower surface of the insulation layer 14. The wiring layer 13 is electrically connected to the connection pads 15P by via wirings 13V formed in the through holes 14X. The wiring layer 13 is formed continuously and integrally with the via wirings 13V. The via wirings 13V, for example, fill the through holes 14X.

The insulation layer 12 is formed on the lower surface of the insulation layer 14 to cover the wiring layer 13. Through holes 12X extend through the insulation layer 12 in the thickness direction to expose parts of the lower surface of the wiring layer 13 in given locations.

The wiring layer 11 is formed on the lower surface of the insulation layer 12. The wiring layer 11 is the lowermost wiring layer of the wiring substrate 10. The wiring layer 11 is electrically connected to the wiring layer 13 by via wirings 11V formed in the through holes 12X. The wiring layer 11 is formed continuously and integrally with the via wirings 11V. The via wirings 11V, for example, fill the through holes 12X.

The through holes 12X and 14X are each tapered to have a diameter (opening width) that decreases from the lower side (close to the wiring layer 11) toward the upper side (close to the wiring layer 15) in FIG. 1. For example, the through holes 12X and 14X each have the shape of a truncated cone such that its lower open end has a larger diameter than its upper open end. That is, the through holes 12X and 14X each have the form of a truncated cone, the diameter of which is smaller toward the wiring layer 15. In an example, the lower open end of the through holes 12X and 14X has a diameter of approximately 10 μm to 60 μm. The upper open end of the through holes 12X and 14X has a diameter of approximately 5 μm to 50 μm.

In the same manner as the through holes 12X and 14X, the via wirings 11V and 13V are each tapered to have a diameter (width) that decreases from the lower side toward the upper side in FIG. 1. In an example, the via wirings 11V and 13V each have the form of a truncated cone, the diameter of which is smaller at the upper surface than at the lower surface.

The solder resist layer 16 is the outermost insulation layer (in this example, lowermost insulation layer) of the wiring substrate 10. The solder resist layer 16 is formed on the lower surface of the insulation layer 12 to cover the wiring layer 11, which is the lowermost wiring layer. The solder resist layer 16 includes openings 16X that expose a portion of the wiring layer 11 as external connection pads P1. The external connection pads P1 are, for example, connected to external connection terminals (not illustrated) used when mounting the wiring substrate 10 on a mount substrate such as a motherboard.

A surface-processed layer may be formed on the lower surface of the wiring layer 11 exposed in the bottom of each opening 16X. Examples of the surface-processed layer include a gold (Au) layer, a nickel (Ni) layer/Au layer (metal layer in which Ni layer and Au layer are stacked in this order), and a Ni layer/palladium (Pd) layer/Au layer (metal layer in which Ni layer, Pd layer, and Au layer are stacked in this order). Other examples of the surface-processed layer include a Ni layer/Pd layer (metal layer in which Ni layer and Pd layer are stacked in this order), and a Pd layer/Au layer (metal layer in which Pd layer and Au layer are stacked in this order). The Au layer is a metal layer formed from Au or a Au alloy. The Ni layer is a metal layer formed from Ni or a Ni alloy. The Pd layer is a metal layer formed from Pd or a Pd alloy. The Au layer, the Ni layer, and the Pd layer may each be, for example, an electroless plating layer formed by an electroless plating process or an electrolytic plating layer formed by an electrolytic plating process. Alternatively, the surface-processed layer may be an organic solderability preservative (OSP) film formed by performing an oxidation-resisting process, such as an OSP process, on the lower surface of the wiring layer 11 exposed in the bottom of the openings 16X. The OSP film may be a coating of an organic compound such as an azole compound or an imidazole compound. When a surface-processed layer is formed on the lower surface of the wiring layer 11, the surface-processed layer is used as the external connection pads P1.

In the present embodiment, the external connection terminals are arranged on the lower surface of the wiring layer 11. Instead, the wiring layer 11 exposed in the bottom of the openings 16X may be used as the external connection terminals. Alternatively, when a surface-processed layer is formed on the lower surface of the wiring layer 11, the surface-processed layer may be used as the external connection terminals.

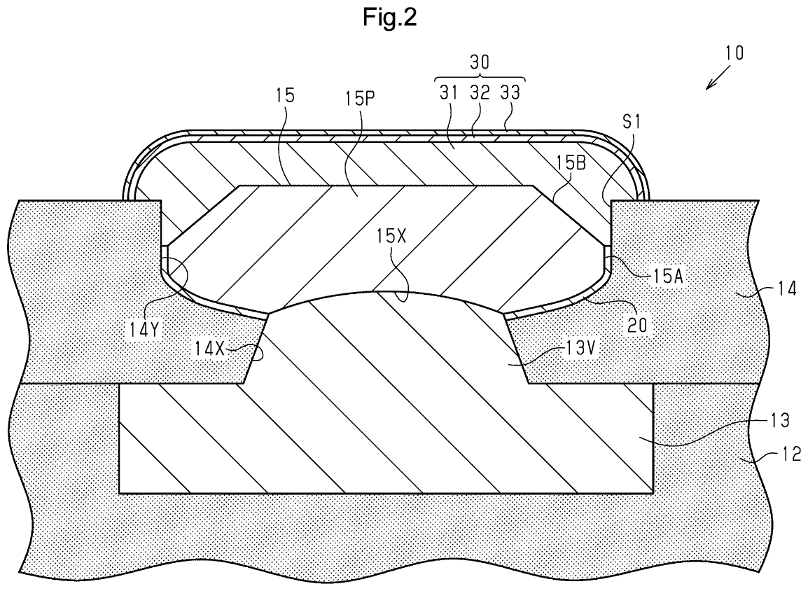

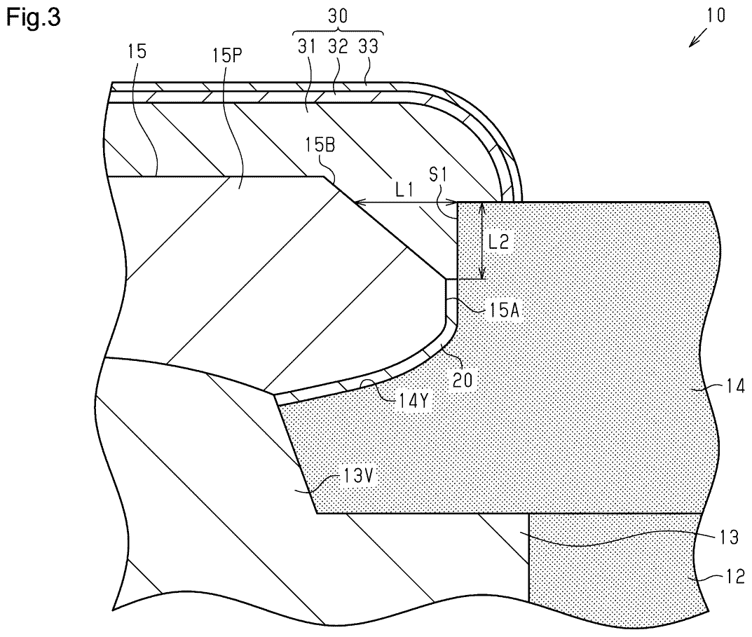

The structures of the adhesion-promoting film 20, the insulation layer 14, the connection pad 15P, and the connection terminal 30 will be described with reference to FIGS. 2 and 3.

### Structure of the Adhesion-Promoting Film 20

As illustrated in FIG. 2, the adhesion-promoting film 20 covers, for example, the entirety of the lower surface of the connection pad 15P exposed from the via wiring 13V. The adhesion-promoting film 20 covers a lower end portion of the side surface of the connection pad 15P and exposes the remaining portion of the side surface of the connection pad 15P. Therefore, the side surface of the connection pad 15P includes a covered surface 15A covered by the adhesion-promoting film 20 and an exposed surface 15B exposed from the adhesion-promoting film 20. In other words, the side surface of the connection pad 15P includes an inclined surface (first surface) inclined outwardly downward from the upper surface of the connection pad 15P and defining the exposed surface 15B and a vertical surface (second surface) bent from the inclined surface and defining the covered surface 15A. In the example of FIG. 2, the covered surface 15A is defined by an entirety of the vertical surface, and the exposed surface 15B is defined by an entirety of the inclined surface. The adhesion-promoting film 20 continuously covers the covered surface 15A and the lower surface of the connection pad 15P. The adhesion-promoting film 20 is in tight contact with and covers the entirety of the covered surface 15A. The adhesion-promoting film 20 exposes, for example, the entirety of the exposed surface 15B.

### Structure of the Insulation Layer 14

The insulation layer 14 covers the adhesion-promoting film 20. In an example, the insulation layer 14 covers the entire surface of the adhesion-promoting film 20. In other words, the adhesion-promoting film 20 is arranged between the connection pad 15P and the insulation layer 14. The adhesion-promoting film 20 improves the adhesion between the connection pad 15P and the insulation layer 14. When the adhesion-promoting film 20 is arranged, the adhesion between the connection pad 15P and the insulation layer 14 is increased as compared with, for example, when the connection pad 15P is in direct contact with the insulation layer 14.

The insulation layer 14 is recessed downward (toward the wiring layer 13) from the upper surface of the insulation layer 14, defining a recess 14Y at a given location. The recess 14Y, for example, overlaps the through hole 14X in plan view. The recess 14Y is continuous with the through hole 14X. The surface of the recess 14Y includes, for example, a bottom surface facing the lower surface of the connection pad 15P and a wall surface facing the side surface of the connection pad 15P. The planar shape of the recess 14Y is, for example, the same as that of the through hole 14X, and is, in the present embodiment, a circle. The planar size of the recess 14Y is greater than that of the upper open end of the through hole 14X. That is, the diameter of the recess 14Y is set to be greater than the diameter of the upper open end of the through hole 14X. Thus, the wall surface of the through hole 14X, the bottom surface of the recess 14Y, and the wall surface of the recess 14Y form a step.

The bottom surface of the recess 14Y covers the entirety of the lower surface of the adhesion-promoting film 20, which covers the lower surface of the connection pad 15P. In an example, the bottom surface of the recess 14Y is in tight contact with and covers the entirety of the lower surface of the adhesion-promoting film 20. In an example, the bottom surface of the recess 14Y is arc-shaped. In an example, the bottom surface of the recess 14Y is curved downward toward the planar center of the recess 14Y.

The wall surface of the recess 14Y, for example, extends in the thickness direction (vertical direction in the drawing) of the insulation layer 14. In an example, the wall surface of the recess 14Y extends substantially perpendicular to the upper surface of the insulation layer 14 in a cross-sectional view. The wall surface of the recess 14Y covers, for example, the entirety of the side surface of the adhesion-promoting film 20, which covers the covered surface 15A of the connection pad 15P. In an example, the wall surface of the recess 14Y is in tight contact with and covers the entirety of the side surface of the adhesion-promoting film 20. The wall surface of the recess 14Y exposes, for example, a portion of the side surface of the connection pad 15P exposed from the adhesion-promoting film 20, defining the exposed surface 15B. An upper portion of the wall surface of the recess 14Y is separated from the exposed surface 15B of the connection pad 15P in a planar direction (sideward direction in the drawing) that is orthogonal to the thickness direction of the insulation layer 14. The upper portion of the wall surface of the recess 14Y faces the exposed surface 15B in the planar direction.

### Structure of the Connection Pad 15P

The connection pad 15P is formed in the recess 14Y. The connection pad 15P is formed on the bottom surface of the recess 14Y with the adhesion-promoting film 20 arranged between the connection pad 15P and the bottom surface of the recess 14Y. The connection pad 15P includes, for example, a lower portion formed in the recess 14Y and an upper portion protruding upward beyond the upper surface of the insulation layer 14.

The lower surface of the connection pad 15P is shaped in conformance with the bottom surface of the recess 14Y. The lower surface of the connection pad 15P is, for example, arc-shaped in a cross-sectional view. The lower surface of the connection pad 15P is, for example, curved downward toward the planar center of the connection pad 15P. The lower surface of the connection pad 15P is, for example, curved more than the upper surface of the connection pads 15P.

The lower surface of the connection pad 15P is recessed upward from the lower surface of the connection pad 15P, defining a recess 15X. The recess 15X is, for example, located in a planar center of the connection pad 15P. The surface of the recess 15X is, for example, arc-shaped in a cross-sectional view. In an example, the surface of the recess 15X is curved upward toward the planar center of the recess 15X.

The via wiring 13V, for example, fills the through hole 14X of the insulation layer 14 and the recess 15X of the connection pad 15P.

The covered surface 15A, which is the side surface of the connection pad 15P covered by the adhesion-promoting film 20, is located at an lower end of the side surface of the connection pad 15P. The covered surface 15A is covered by the wall surface of the recess 14Y with the adhesion-promoting film 20 arranged between the covered surface 15A and the wall surface of the recess 14Y.

The exposed surface 15B, which is the side surface of the connection pad 15P exposed from the adhesion-promoting film 20, is located above the covered surface 15A. The exposed surface 15B includes an inclined surface that is inclined so as to approach the planar center of the connection pad 15P as the exposed surface 15B extends toward the upper surface of the connection pad 15P from the side of the lower surface of the connection pad 15P. In other words, the exposed surface 15B is inclined so as to approach the wall surface of the recess 14Y as the exposed surface 15B extends from the upper surface of the connection pad 15P toward the lower surface of the connection pad 15P. In the present embodiment, the exposed surface 15B is, for example, an inclined plane extending straight without any irregularities in a cross-sectional view. In the present embodiment, the exposed surface 15B is inclined at a fixed inclination angle. However, the exposed surface 15B does not necessarily have to be flat. The exposed surface 15B may partially or entirely have an outward curve or an inward curve.

The exposed surface 15B is separated from the wall surface of the recess 14Y in the planar direction. In other words, a first gap S1 is arranged between the exposed surface 15B and the wall surface of the recess 14Y. The first gap S1 is, for example, continuously formed along the entire perimeter of the connection pad 15P.

As illustrated in FIG. 3, the width of the first gap S1 is, for example, decreased in a direction from the upper surface of the insulation layer 14 toward the bottom surface of the recess 14Y. The first gap S1 has, for example, a width dimension L1 in the width direction (sideward direction in the drawing) and a depth dimension L2 in the depth direction (vertical direction in the drawing). The width dimension L1 is greater than the depth dimension L2.

As illustrated in FIG. 2, for example, the upper surface of the connection pad 15P protrudes upward beyond the upper surface of the insulation layer 14. The upper surface of the connection pad 15P, for example, extends in the planar direction. The amount of protrusion of the connection pad 15P from the upper surface of the insulation layer 14, that is, the thickness of the connection pad 15P from the upper surface of the insulation layer 14 to the upper surface of the connection pad 15P, may be, for example, approximately 2 μm to 5 μm.

The connection pad 15P may have any planar shape and any planar size. In the present embodiment, the planar shape of the connection pad 15P is the same as the planar shape of the recess 14Y and, in the present embodiment, is a circle. The connection pad 15P is tapered so that the diameter (width) is decreased from the lower surface of the connection pad 15P toward the upper surface of the connection pad 15P. In an example, the connection pad 15P has the form of a truncated cone in which the upper surface has a smaller diameter than the lower surface. In an example, the area of the upper surface of the connection pad 15P is smaller than the area of the lower surface of the connection pad 15P. The upper surface of the connection pad 15P and the side surface of the connection pad 15P (in the present example, exposed surface 15B) form an inner angle that is, for example, set to an obtuse angle

The diameter (width) of the upper surface of the connection pad 15P is, for example, set to be smaller than the diameter (width) of the upper open end of the recess 14Y. The diameter (width) of the upper open end of the recess 14Y is, for example, set to be greater than or equal to the diameter (width) of the lower surface of the connection pad 15P. The diameter (width) of the upper surface of the wiring layer 13 is, for example, set to be greater than or equal to the diameter (width) of the lower surface of the connection pad 15P.

### Structure of the Connection Terminal 30

The connection terminal 30 is formed on the connection pad 15P. The connection terminal 30 covers the upper surface of the connection pad 15P and the side surface of the connection pad 15P. The connection terminal 30 fills the first gap S1 between the side surface of the connection pad 15P and the wall surface of the recess 14Y. In an example, the connection terminal 30 covers a portion of the upper surface of the insulation layer 14. The connection terminal 30 may be, for example, a metal layer such as a Au layer, a Ni layer/Au layer, a Ni layer/Pd layer/Au layer, a Ni layer/Pd layer, and a Pd layer/Au layer.

In the present embodiment, the connection terminal 30 has a structure in which a metal layer 31, a metal layer 32, and a metal layer 33 are sequentially stacked.

In an example, the metal layer 31 covers the entirety of the upper surface of the connection pad 15P and the entirety of the side surface of the connection pad 15P exposed from the insulation layer 14 and the adhesion-promoting film 20 (i.e., the entirety of the exposed surface 15B). The metal layer 31 covers the entirety of the wall surface of the recess 14Y exposed from the connection pad 15P and the adhesion-promoting film 20. The metal layer 31 fills the first gap S1 between the side surface of the connection pad 15P and the wall surface of the recess 14Y. The metal layer 31 covers the upper surface of the insulation layer 14 located around the recess 14Y. The metal layer 31, for example, protrudes outward from the side surface of the connection pad 15P in the planar direction. The portion of the side surface of the metal layer 31 protruding upward beyond the upper surface of the insulation layer 14, that is, the side surface of the metal layer 31 exposed from the insulation layer 14, is, for example, arc-shaped in a cross-sectional view. The side surface of the metal layer 31 exposed from the insulation layer 14 is curved toward the planar center of the metal layer 31 in a direction toward the upper surface of the metal layer 31. The upper surface and the side surface of the metal layer 31 form an upper edge of the metal layer 31 that is arc-shaped in a cross-sectional view. Preferably, the material of the metal layer 31 is, for example, a conductive material having a higher adhesion to the connection pad 15P (in this example, Cu layer) than the metal forming the metal layer 32. In the present embodiment, the metal layer 31 is a Ni layer.

The metal layer 32 covers the entire surface of the metal layer 31. The metal layer 32 covers the entirety of the upper surface of the metal layer 31 and the entirety of the side surface of the metal layer 31 exposed from the insulation layer 14. In the present embodiment, the metal layer 32 is a Pd layer. The metal layer 33 covers the entire surface of the metal layer 32. The metal layer 33 covers the entirety of the upper surface of the metal layer 32 and the entirety of the side surface of the metal layer 32. In the present embodiment, the metal layer 33 is a Au layer.

The thickness of the metal layer 31, which is from the upper surface of the connection pad 15P to the upper surface of the metal layer 31, may be, for example, approximately 1 μm to 9 μm. The thickness of the metal layer 32 may be, for example, approximately 80 nm to 150 nm. The thickness of the metal layer 33 may be, for example, approximately 10 nm to 90 nm.

### Structure of Semiconductor Device 40

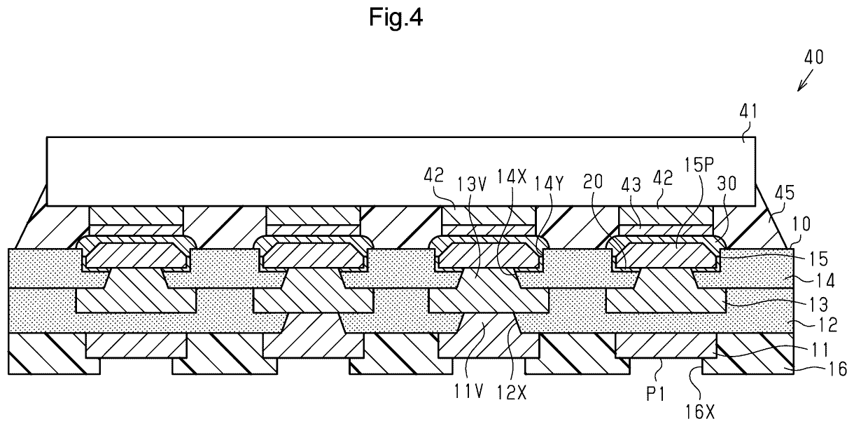

The structure of a semiconductor device 40 will now be described with reference to FIG. 4.

As illustrated in FIG. 4, the semiconductor device 40 includes the wiring substrate 10, one or more (in the present embodiment, one) semiconductor elements 41, and an underfill resin 45.

### Structure of the Semiconductor Element 41

The semiconductor element 41 includes connection terminals 42 formed on a circuit formation surface (in this example, lower surface) of the semiconductor element 41. The semiconductor element 41 is, for example, flip-chip-mounted on the connection terminals 30 of the wiring substrate 10. The connection terminals 42 of the semiconductor element 41 are electrically connected to the connection terminals 30 formed on the surface of the connection pads 15P. The connection terminals 42 are, for example, electrically connected to the connection terminals 30 via bonding members 43. Thus, the semiconductor element 41 is electrically connected to the connection pads 15P via the connection terminals 42, the bonding members 43, and the connection terminals 30.

The semiconductor element 41 may be, for example, a logic chip such as a central processing unit (CPU) chip or a graphics processing unit (GPU) chip. Further, the semiconductor element 41 may be, for example, a memory chip such as a dynamic random-access memory (DRAM) chip, a static random-access memory (SRAM) chip, or a flash memory. When more than one semiconductor element 41 is mounted on the wiring substrate 10, a logic chip may be mounted in combination with a memory chip on the wiring substrate 10.

### Structure of the Connection Terminal 42

The connection terminal 42 may be, for example, a metal post. The connection terminal 42 is, for example, rod-shaped connection terminals extending downward from the circuit formation surface of the semiconductor element 41. In the present embodiment, the connection terminal 42 is cylindrical-rod-shaped. The material of the connection terminals 42 may be, for example, copper or a copper alloy. In addition to a metal post, for example, a metal bump may also be used as the connection terminal 42.

### Structure of the Bonding Member 43

The bonding member 43 is, for example, bonded to the connection terminal 42 and the connection terminal 30. The bonding member 43 electrically connects the connection terminal 42 and the connection terminal 30. The bonding member 43 may be, for example, a solder layer. The material of the solder layer may be, for example, lead (Pb)-free solder such as tin (Sn)-silver (Ag)-based solder, Sn-Cu-based solder, or Sn-Ag-Cu-based solder. The thickness of each bonding member 43 may be, for example, approximately 5 μm to 30 μm.

### Structure of the Underfill Resin 45

The underfill resin 45 fills the gap between the wiring substrate 10 and the semiconductor element 41. The underfill resin 45 fills the gap between the upper surface of the insulation layer 14 and the lower surface of the semiconductor element 41. The underfill resin 45 encapsulates the connection terminals 30, the bonding members 43, and the connection terminals 42. The material of the underfill resin 45 may be, for example, an insulating resin such as epoxy resin.

In the present embodiment, the metal layer 31 is an example of a first metal layer. The metal layer 32 is an example of a second metal layer.

### Method for Manufacturing the Wiring Substrate 10

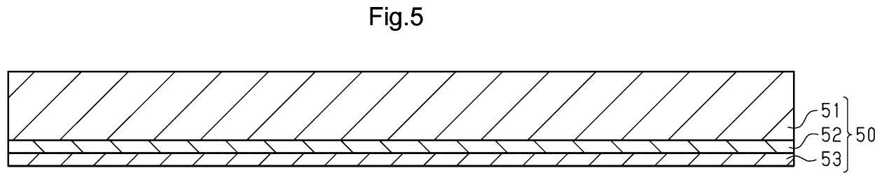

A method for manufacturing the wiring substrate 10 will now be described with reference to FIGS. 5 to 22. To facilitate understanding, portions that ultimately become elements of the wiring substrate 10 are indicated by reference characters used to denote the final elements.

In the step illustrated in FIG. 5, a support 50 is prepared. The support 50 has, for example, a structure in which a metal foil 52 and a metal film 53 are sequentially formed on the lower surface of a base 51. The base 51 is formed from, for example, a prepreg obtained by impregnating a reinforcement material such as a woven or non-woven cloth of glass fibers, aramid fibers, or liquid crystal polymer (LCP) fibers with a thermosetting insulative resin, such as an epoxy resin or a polyimide resin. The metal foil 52 covers, for example, the entirety of the lower surface of the base 51. The metal foil 52 is, for example, a copper foil. The metal film 53 covers, for example, the entirety of the lower surface of the metal foil 52. The metal film 53 is, for example, a copper film. The material of the metal foil 52 is not limited to copper and may be a metal other than copper. The material of the metal film 53 is not limited to copper and may be a metal other than copper.

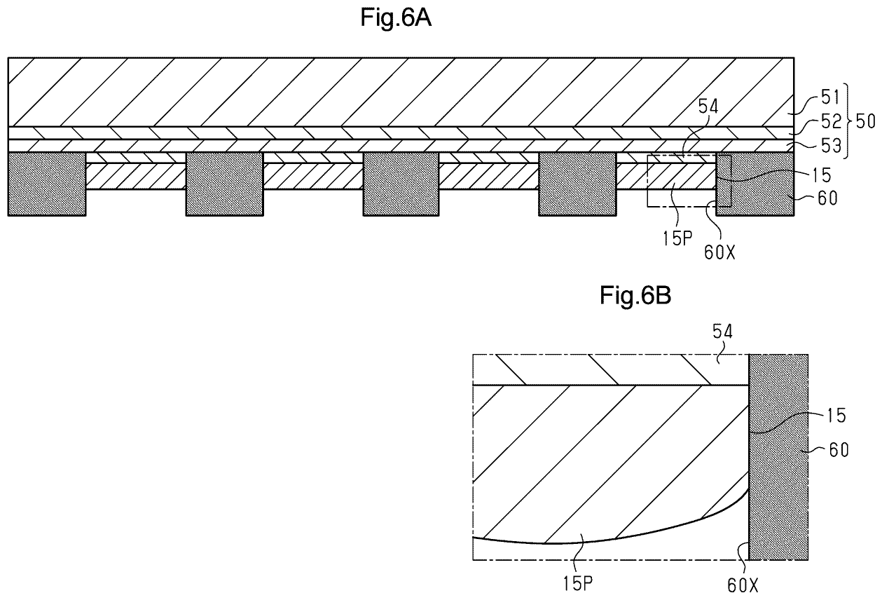

In the step illustrated in FIG. 6A, a resist layer 60 having an opening pattern 60X is formed on the lower surface of the metal film 53 of the support 50. The opening pattern 60X exposes portions of the lower surface of the metal film 53 that correspond to the region where the wiring layer 15 is formed.

Subsequently, electrolytic plating is performed on the metal film 53 so that the resist layer 60 serves as a plating mask and the metal film 53 serves as a plating power feeding layer. In an example, electrolytic plating (in this case, electrolytic Ni plating) is performed on the lower surface of the metal film 53 exposed in the opening pattern 60X of the resist layer 60. This forms the metal layer 54 on the lower surface of the metal film 53 exposed from the opening pattern 60X. The material of the metal layer 54 may be different from nickel as long as it is a conductive material that may be etched and removed from the wiring layer 15 in a subsequent step. Then, electrolytic plating (in this case, electrolytic Cu plating) is performed on the lower surface of the metal layer 54 so that the metal film 53 serves as a plating power feeding layer. This forms the wiring layer 15 including the connection pads 15P on the lower surface of the metal layer 54. In this step, as illustrated in FIG. 6B, the lower surface of the connection pad 15P is curved to bulge downward in a cross-sectional view. In other words, in the present embodiment, the plating condition of electrolytic plating is adjusted so that the lower surface of the connection pad 15P is curved. In an example, the composition of a plating bath or the electrodeposition condition may be adjusted so that the lower surface of the connection pad 15P is curved to bulge downward.

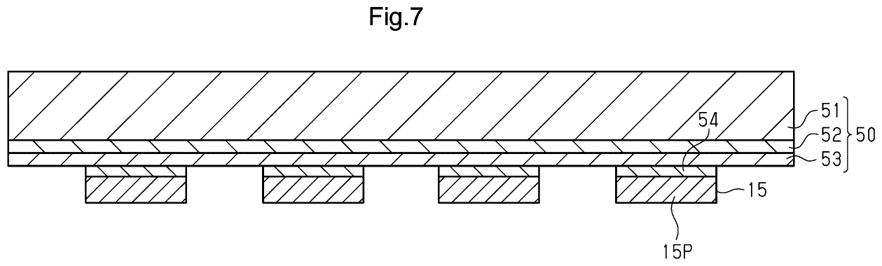

In the step illustrated in FIG. 7, the resist layer 60 illustrated in FIG. 6 is removed using an alkaline stripping solution (e.g., organic amine stripping solution, caustic soda, acetone, ethanol, or the like).

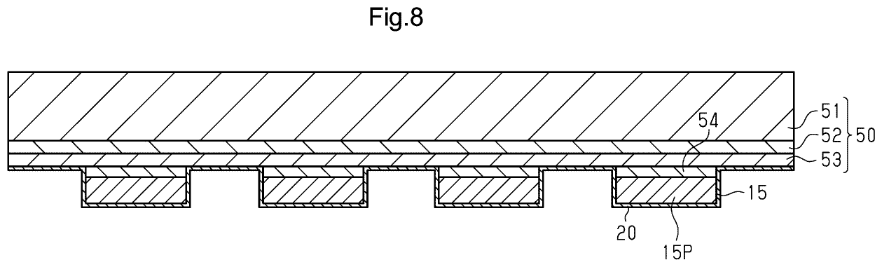

In the step illustrated in FIG. 8, the adhesion-promoting film 20 is formed to cover the lower surface and the side surface of each connection pad 15P. In the present example, the adhesion-promoting film 20 covers the entirety of the lower surface and the entirety of the side surface of the connection pad 15P. In the present example, the adhesion-promoting film 20 covers the entirety of the side surface of the metal layer 54. In the present example, the adhesion-promoting film 20 covers the entirety of the lower surface of the metal film 53 exposed from the metal layer 54. The adhesion-promoting film 20 is formed from, for example, a silane coupling agent.

When the adhesion-promoting film 20 is formed from, for example, a silane coupling agent, for example, the structural body illustrated in FIG. 7 may be immersed in a diluted solution of the silane coupling agent. Alternatively, the diluted solution of the silane coupling agent may be sprayed onto the lower surface and the side surface of the connection pads 15P to form the adhesion-promoting film 20. The concentration of the diluted solution of the silane coupling agent is 0.1% to 10%, preferably 0.5% to 5%. In this state, the thickest portion of the adhesion-promoting film 20 may have a thickness of, for example, approximately 20 nm to 300 nm. Subsequently, the structural body is washed with water, and the adhesion-promoting film 20 is partially removed using a removing liquid such as an acidic solution. Then, the structural body is dried. As a result, the adhesion-promoting film 20 having a thickness of approximately 10 nm to 200 nm is obtained.

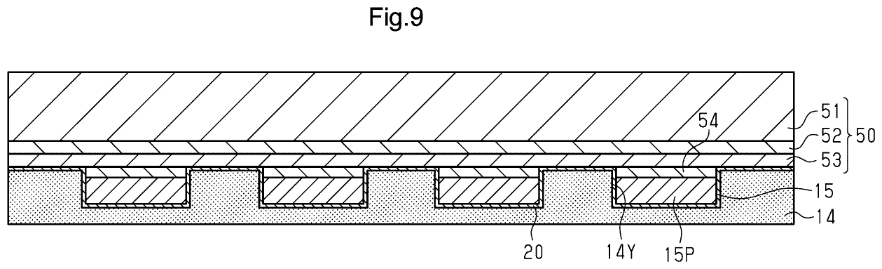

In the step illustrated in FIG. 9, the insulation layer 14 is formed on the lower surface of the adhesion-promoting film 20 to cover the wiring layer 15 and the adhesion-promoting film 20. In an example, when a resin film is used as the insulation layer 14, the lower surface of the adhesion-promoting film 20 is laminated with the resin film. The resin film is heated at a curing temperature or higher (e.g., approximately 130° C. to 200° C.) while being pressed so that the resin film is cured to form the insulation layer 14. The resin film may be, for example, a film of a thermosetting resin including an epoxy resin as a main component. When a liquid or paste of insulative resin is used as the insulation layer 14, the liquid or paste of insulative resin is applied to the lower surface of the adhesion-promoting film 20 through a spin coating process or the like. The applied insulating resin is heated at a curing temperature or higher so that the insulating resin is cured to form the insulation layer 14. The liquid or paste of insulating resin may be, for example, a thermosetting resin including an epoxy resin as a main component.

In this step, the metal layer 54, the connection pads 15P, and the adhesion-promoting film 20, which covers the metal layer 54 and the connection pads 15P, are embedded in the insulation layer 14. In other words, recesses 14Y are formed in the insulation layer 14 accommodating the metal layer 54 and the connection pads 15P, which are covered by the adhesion-promoting film 20.

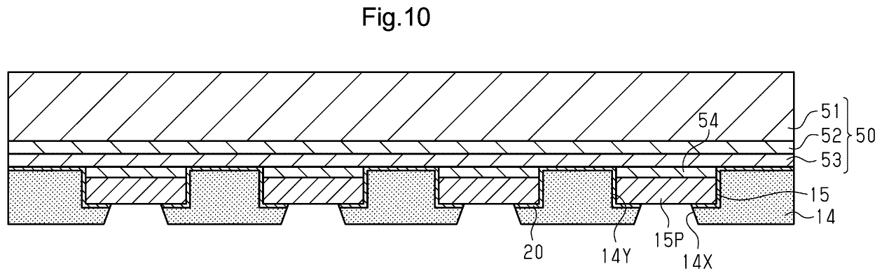

In the step illustrated in FIG. 10, the through holes 14X are formed in given locations of the insulation layer 14 to expose parts of the lower surfaces of the connection pads 15P. The through holes 14X extend through the insulation layer 14 and the adhesion-promoting film 20 in the thickness direction. The through holes 14X are continuous with the recesses 14Y, respectively. The through holes 14X may be formed by, for example, laser drilling using CO₂ laser, UV-YAG laser, or the like.

When the through holes 14X are formed by laser drilling, a desmear process is performed to remove resin smears from the lower surface of the connection pads 15P exposed at the bottom of the through holes 14X. The desmearing process of this step may be, for example, a wet desmearing process using a potassium permanganate solution.

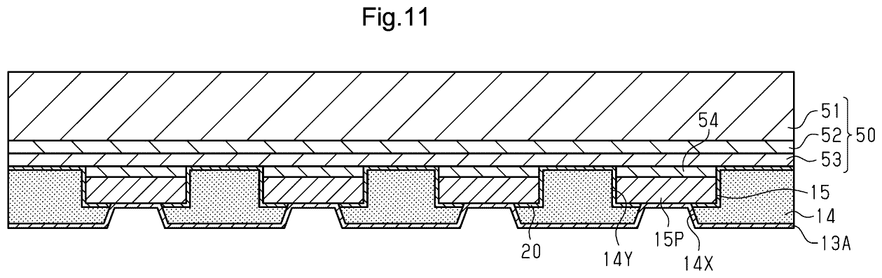

In the step illustrated in FIG. 11, a seed layer 13A is formed to cover the entirety of the lower surface of the insulation layer 14, the entirety of the wall surface of each through hole 14X, and the entirety of the lower surface of the connection pad 15P exposed at the bottom surface of the through hole 14X. The seed layer 13A may be formed by, for example, sputtering or electroless plating.

In an example in which the seed layer 13A is formed by sputtering, titanium is first sputtered and deposited on the lower surface of the insulation layer 14 and the wall surfaces of the through holes 14X to form a Ti layer that covers the lower surface of the insulation layer 14 and the wall surfaces of the through holes 14X. Then, copper is sputtered and deposited on the Ti layer to form a Cu layer. This forms the seed layer 13A with a double-layered structure (Ti layer/Cu layer). Alternatively, when forming the seed layer 13A by electroless plating, for example, electroless copper plating may be performed to form the seed layer 13A including a Cu layer (single-layered structure).

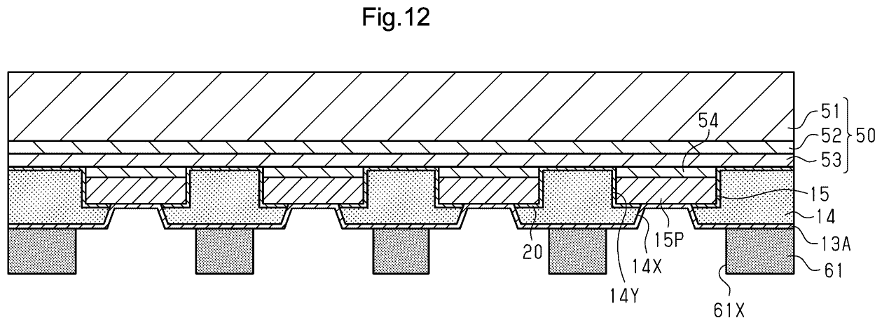

In the step illustrated in FIG. 12, a resist layer 61 having an opening pattern 61X at a given location is formed on the seed layer 13A. The opening pattern 61X exposes parts of the seed layer 13A corresponding to a region in which the wiring layer 13 (refer to FIG. 1) is formed. The material of the resist layer 61 may, for example, resist plating in the plating process performed in the following step. The material of the resist layer 61 may be, for example, the same as the material of the resist layer 60 illustrated in FIG. 6A. The resist layer 61 may be formed, for example, by the same process as the resist layer 60 illustrated in FIG. 6A.

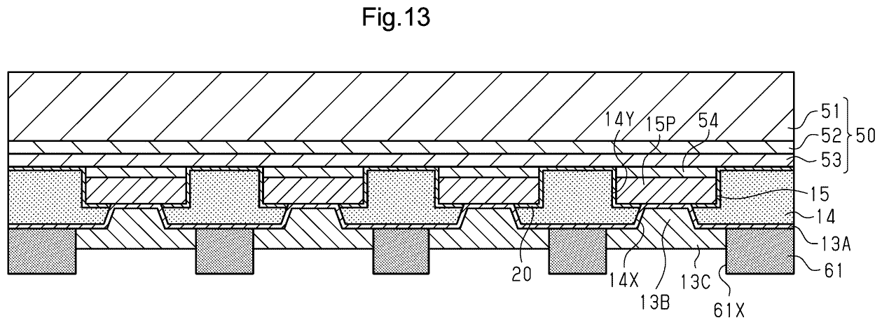

In the step illustrated in FIG. 13, electrolytic plating (in this case, electrolytic Cu plating) is performed on the seed layer 13A exposed from the opening pattern 61X of the resist layer 61 so that the resist layer 61 serves as a plating mask and the seed layer 13A serves as a plating power feeding layer. As a result, a metal layer 13B is formed to fill the through holes 14X on an inner side of the seed layer 13A, and a metal layer 13C is formed on the lower surface of the seed layer 13A formed on the lower surface of the insulation layer 14.

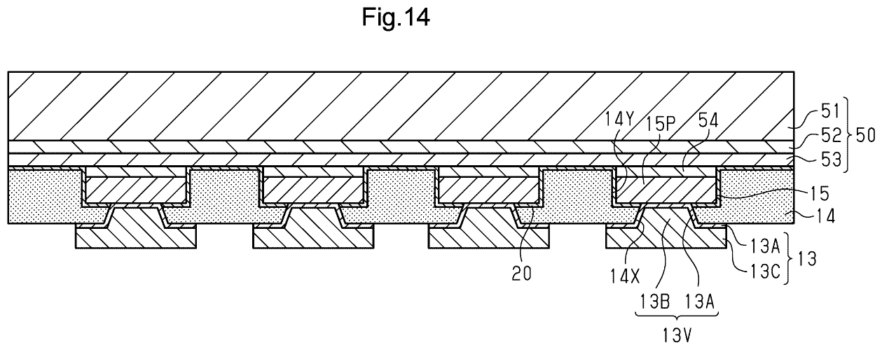

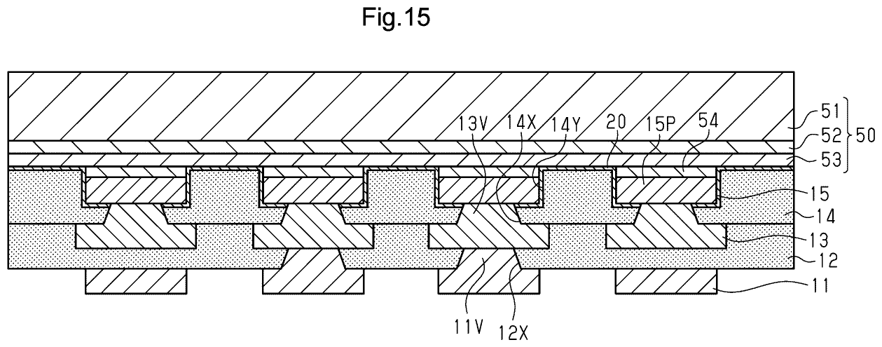

In the step illustrated in FIG. 14, the resist layer 61 illustrated in FIG. 13 is removed by an alkali stripping solution. Subsequently, etching is performed using the metal layers 13B and 13C as an etching mask to remove unwanted portions of the seed layer 13A. For example, when the seed layer 13A is formed of a Ti layer and a Cu layer, unwanted portions of the Cu layer are removed by wet etching using a sulfuric acid-hydrogen peroxide etchant. Then, for example, unwanted portions of the Ti layer are removed by dry etching using an etching gas such as CF₄ or wet etching using a KOH-based etchant. As a result of this step, the via wirings 13V are formed in the through holes 14X and include the seed layer 13A and the metal layer 13B formed in the through holes 14X. In addition, the wiring layer 13 is formed on the lower surface of the insulation layer 14 and includes the seed layer 13A and the metal layer 13C formed on the lower surface of the insulation layer 14. As described above, the via wirings 13V and the wiring layer 13 are formed by a semi-additive process. FIGS. 15 to 22, which are used in the following description, do not illustrate the seed layer 13A and the metal layers 13B and 13C, but instead illustrate them as the via wirings 13V and the wiring layer 13.

In the step illustrated in FIG. 15, steps similar to those illustrated in FIGS. 9 to 14 are performed to stack the insulation layer 12 and the wiring layer 11 on the lower surface of the insulation layer 14.

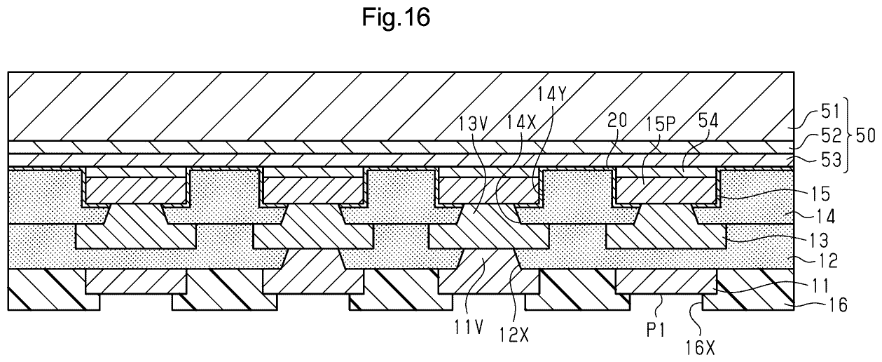

In the step illustrated in FIG. 16, the solder resist layer 16 including the openings 16X, which expose parts of the lower surface of the wiring layer 11 as the external connection pads P1, is formed on the lower surface of the insulation layer 12. The solder resist layer 16 may be formed, for example, by laminating a photosensitive solder resist film or applying a liquid solder resist and patterning the resist into a desired shape.

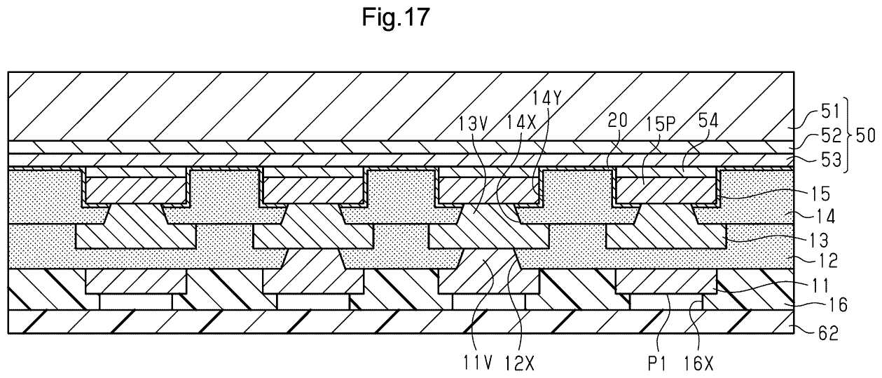

In the step illustrated in FIG. 17, a protective film 62 is formed on the lower surface of the solder resist layer 16 to cover the wiring layer 11 and the solder resist layer 16. The material of the protective film 62 may be, for example, polyimide, polyolefin, or polyvinyl chloride.

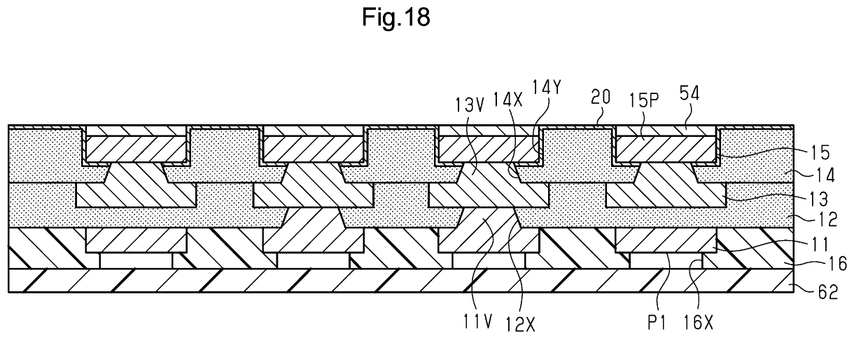

Next, the support 50 is removed. An example of a process for removing the support 50 will be described below. First, the base 51 is removed from the support 50. In an example, the base 51 is mechanically separated from the metal foil 52. Then, the metal foil 52 is removed. In an example, the metal foil 52 is mechanically separated from the metal film 53. Then, the metal film 53 is removed. In an example, the metal film 53 is etched and removed selectively from the metal layer 54, which is a Ni layer. As a result, as illustrated in FIG. 18, the upper surface of the metal layer 54 and the upper surface of the adhesion-promoting film 20 are exposed to the exterior. Since the wiring layer 11 is covered by the protective film 62, the metal film 53 is not removed by the etching.

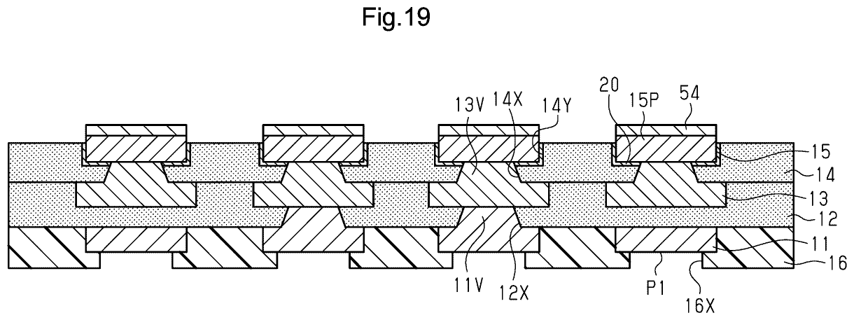

As illustrated in FIG. 19, the protective film 62, which is illustrated in FIG. 18, is removed. In an example, the protective film 62 is mechanically separated from the solder resist layer 16.

Next, the adhesion-promoting film 20 and the insulation layer 14 are thinned from the side where the upper surfaces of the adhesion-promoting film 20 and the insulation layer 14 are located. In this step, the adhesion-promoting film 20 and the insulation layer 14 are thinned from the upper surface so that upper parts of the connection pads 15P protrude upward beyond the upper surface of the insulation layer 14. In this step, the upper parts of the connection pads 15P protrude upward beyond the adhesion-promoting film 20 and the insulation layer 14 and are exposed from the adhesion-promoting film 20 and the insulation layer 14. In this step, the thinning process may be performed by, for example, plasma etching and wet blasting. In an example, in the thinning process, plasma etching is performed, and then wet blasting is performed.

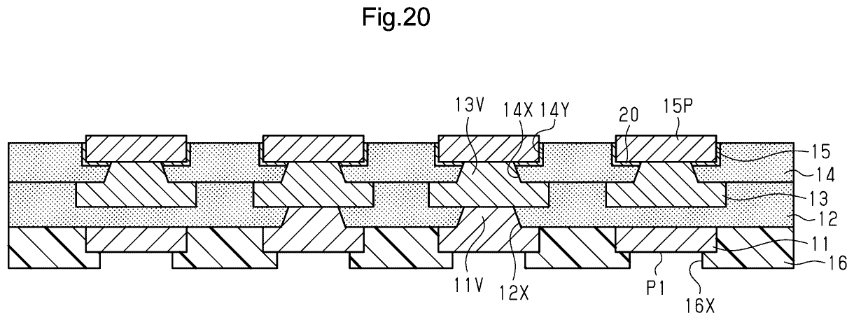

In the step illustrated in FIG. 20, the metal layer 54 illustrated in FIG. 19 is removed. In an example, the metal layer 54 is removed by etching. In the etching of this step, while the metal layer 54, which is a Ni layer, is preferentially etched and removed, the wiring layer 15, which is a Cu layer, is slightly etched and removed. As a result, a slight gap (not illustrated) is formed between the side surface of each connection pad 15P and the adhesion-promoting film 20.

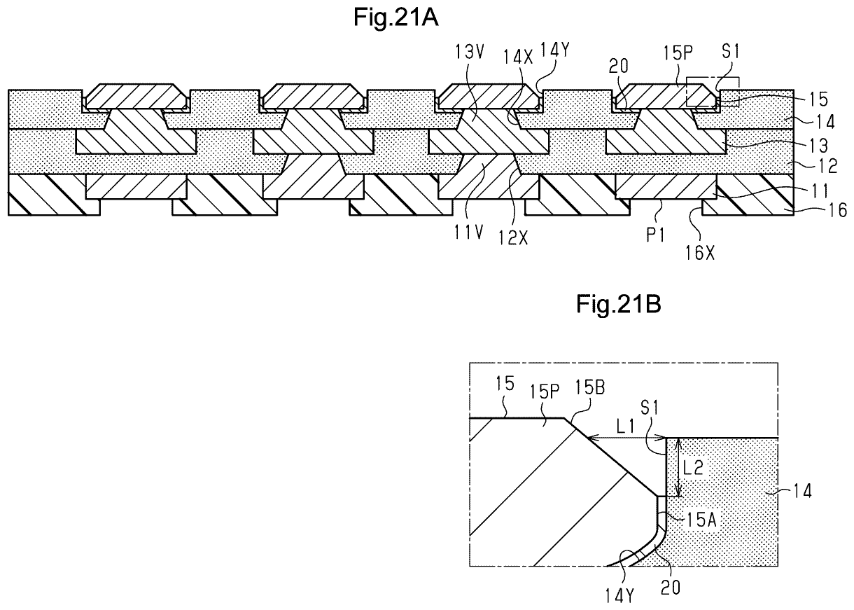

In the steps illustrated in FIGS. 21A and 21B, a portion of each connection pad 15P is etched so that the first gap S1 is formed between the side surface of the connection pad 15P and the wall surface of the recess 14Y. In an example, soft etching is performed to selectively remove a portion of the connection pad 15P with respect to the insulation layer 14 to form the first gap S1. A portion of the upper surface of the connection pad 15P and a portion of the side surface of the connection pad 15P are etched to reduce the thickness (vertical dimension) and the width (sideward direction) of the connection pad 15P. This forms the first gap S1 between the side surface of the connection pad 15P and the wall surface of the recess 14Y. In this step, a soft etching solution permeates into a slight gap, which is formed in the step illustrated in FIG. 20 (i.e., slight gap between the side surface of the connection pad 15P and the side surface of the adhesion-promoting film 20), to etch the connection pad 15P. However, progress of the etching is limited by the adhesion-promoting film 20, which is formed between the side surface of the connection pad 15P and the wall surface of the recess 14Y. Therefore, the etching progresses in the horizontal direction (planar direction) toward the planar center of the connection pad 15P more preferentially than in the downward direction along the side surface of the connection pad 15P. As illustrated in FIG. 21B, in the first gap S1, the width dimension L1, which extends in the planar direction, is larger than the depth dimension L2, which extends in the downward direction.

In this step, a portion of the side surface of the connection pad 15P, that is, an upper portion of the side surface of the connection pad 15P, is exposed from the adhesion-promoting film 20. In this step, the amount of the connection pad 15P removed by etching is increased toward the upper surface of the connection pad 15P. Thus, the exposed surface 15B, which is the side surface of the connection pad 15P exposed from the adhesion-promoting film 20, is inclined so as to approach the planar center of the connection pad 15P as the exposed surface 15B extends toward the upper surface of the connection pad 15P.

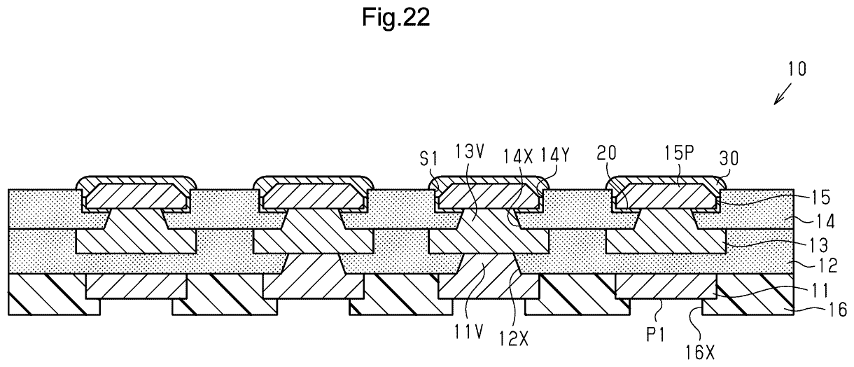

In the step illustrated in FIG. 22, the connection terminals 30 are formed on the connection pads 15P. For example, as illustrated in FIG. 2, the metal layer 31 is formed on the connection pads 15P. The metal layer 31 may be formed through, for example, an electroless plating process, in this case, an electroless Ni plating process. The metal layer 31 covers the upper surfaces of the connection pads 15P and fills the first gap S1. In this step, for example, if a gap is formed between the lower surface of the connection pad 15P and the bottom surface of the recess 14Y by soft etching performed in the previous step, poor distribution of a plating solution may result in non-application of plating to the lower surface of the connection pad 15P. When such non-application of plating occurs, the reliability of electrical connection between the metal layer 31 and the connection pad 15P is decreased. In this regard, in the present embodiment, the adhesion-promoting film 20 is formed between the connection pad 15P and the wall surface of the recess 14Y. This limits progress of downward etching between the connection pad 15P and the wall surface of the recess 14Y. Consequently, formation of a gap between the lower surface of the connection pad 15P and the bottom surface of the recess 14Y is limited. Therefore, since formation of a gap causing non-application of plating is limited, non-application of plating caused by poor distribution of the plating solution is appropriately limited.

Subsequently, the metal layer 32 is formed to cover the entire surface of the metal layer 31 exposed from the insulation layer 14. The metal layer 32 may be formed through an electroless plating process, in this case, an electroless Pd plating process. The metal layer 33 is formed to cover the entire surface of the metal layer 32. The metal layer 33 may be formed through an electroless plating process, in this case, an electroless Au plating process. As a result, the connection terminals 30 having the metal layers 31, 32, and 33 are formed. The wiring substrate 10 is manufactured through the steps described above.

### Advantages

The present embodiment has the advantages described below.

(1) The wiring substrate 10 includes the insulation layer 14, the recess 14Y recessed downward from the upper surface of the insulation layer 14, the connection pad 15P formed in the recess 14Y, and the adhesion-promoting film 20 arranged between a portion of the side surface of the connection pad 15P and a portion of the wall surface of the recess 14Y. The wiring substrate 10 includes the first gap S1 defined between the exposed surface 15B, which is a portion of the side surface of the connection pad 15P, and the wall surface of the recess 14Y. The wiring substrate 10 includes the connection terminal 30 covering the upper surface of the connection pad 15P and filling the first gap S1. The exposed surface 15B of the connection pad 15P is located above the covered surface 15A, which is a portion of the side surface of the connection pad 15P covered by the adhesion-promoting film 20. The exposed surface 15B of the connection pad 15P is inclined so as to approach the planar center of the connection pad 15P as the exposed surface 15B extends toward the upper surface of the connection pad 15P.

In this structure, the adhesion-promoting film 20 is formed between the wall surface of the recess 14Y and the covered surface 15A, which is a portion of the side surface of the connection pad 15P located below the exposed surface 15B. The adhesion-promoting film 20 improves the adhesion between the connection pad 15P and the insulation layer 14. Such arrangement of the adhesion-promoting film 20 limits progress of downward etching between the connection pad 15P and the wall surface of the recess 14Y. When soft etching is performed on the connection pad 15P, the above structure appropriately limits progress of etching to the lower surface of the connection pad 15P. Therefore, removal of the lower surface of the connection pad 15P by etching is appropriately limited. Accordingly, formation of a gap between the lower surface of the connection pad 15P and the bottom surface of the recess 14Y is appropriately limited. Thus, when a plating solution is used to form the connection terminal 30, non-application of plating caused by poor distribution of the plating solution is limited. As a result, decreases in the reliability of electrical connection between the connection terminal 30 and the connection pad 15P caused by non-application of plating are limited. In other words, the reliability of electrical connection between the connection terminal 30 and the connection pad 15P is improved as compared to when non-application of plating occurs.

(2) The adhesion-promoting film 20 continuously covers the lower surface of the connection pad 15P and the covered surface 15A, which is a portion of the side surface of the connection pad 15P. When soft etching is performed on the connection pad 15P, progress of etching to the lower surface of the connection pad 15P is further appropriately limited. Thus, formation of a gap between the lower surface of the connection pad 15P and the bottom surface of the recess 14Y is further appropriately limited.

(3) In the first gap S1, the depth dimension L2 in the depth direction of the first gap S1 is smaller than the width dimension L1 in the width direction, which is orthogonal to the depth direction. This structure increases the surface area of the exposed surface 15B exposed to the first gap S1, thereby increasing the area of contact of the exposed surface 15B with the connection terminal 30 filling the first gap S1. Therefore, the reliability of electrical connection between the connection terminal 30 and the connection pad 15P is increased.

### MODIFIED EXAMPLES

The embodiment described above may be modified as follows. The above-described embodiment and the following modified examples may be combined if the combined modified examples remain technically consistent with each other.

In the embodiment, the range in which the adhesion-promoting film 20 is formed may be changed.

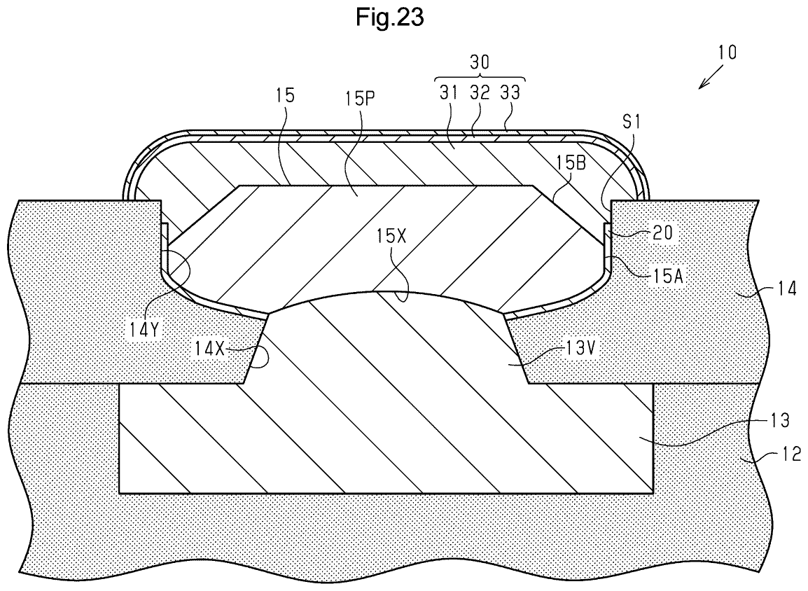

In an example, as illustrated in FIG. 23, the formation range of the adhesion-promoting film 20 may extend upward. For example, the adhesion-promoting film 20 may cover a portion of the wall surface of the recess 14Y facing the exposed surface 15B. In other words, the adhesion-promoting film 20 may cover a portion of the wall surface of the recess 14Y defining the first gap S1.

In an example, the adhesion-promoting film 20 may cover the entirety of the wall surface of the recess 14Y.

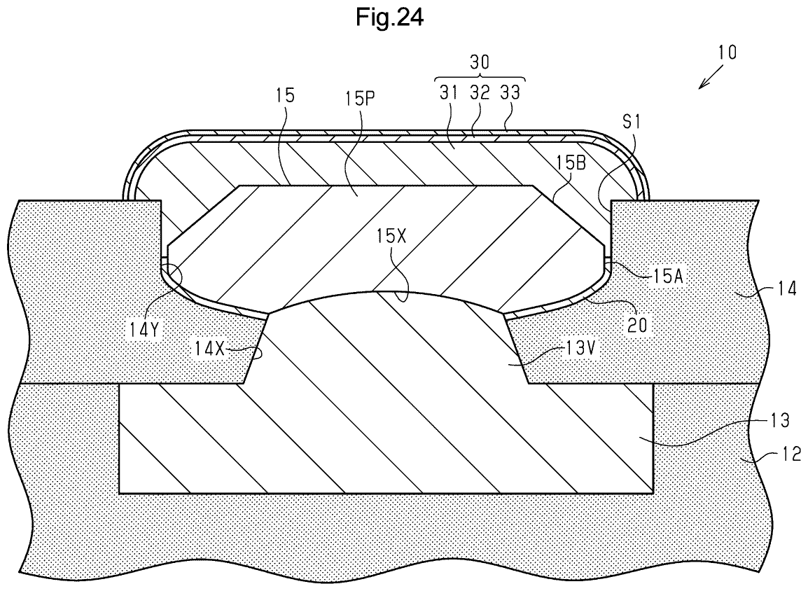

In an example, as illustrated in FIG. 24, the adhesion-promoting film 20 may be arranged below the lower end of the exposed surface 15B, which is an inclined surface. In other words, in the example of FIG. 24, the exposed surface 15B is defined by an entirety of the inclined surface (first surface) and an upper portion of the vertical surface (second surface) of the side surface of the connection pad 15P, and the covered surface 15A is defined by a remaining lower portion of the vertical surface (second surface) of the side surface of the connection pad 15P. Therefore, the connection terminal 30 extends into a space (first gap S1) between the vertical surface of the side surface of the connection pad 15P and the wall surface of the recess 14Y.

The structure of the connection pad 15P in the embodiment may be changed.

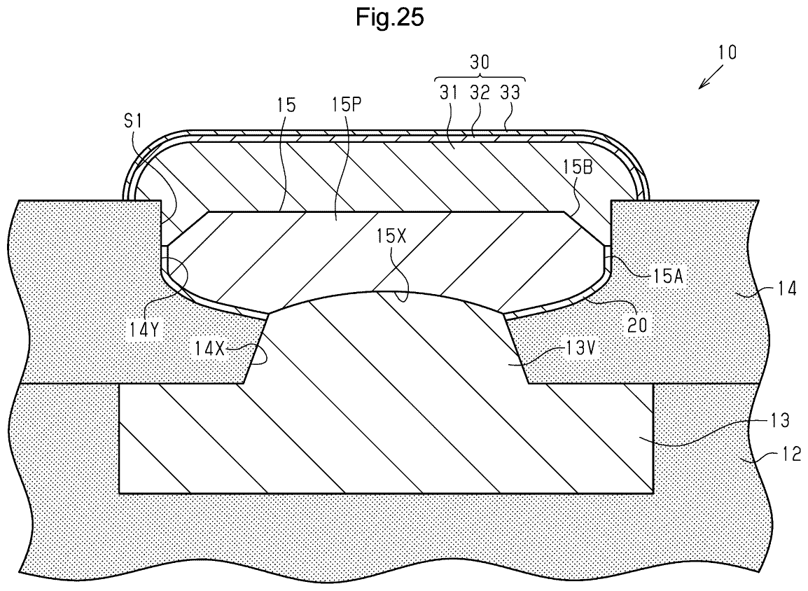

For example, as illustrated in FIG. 25, the upper portion of the connection pad 15P may be arranged below the upper surface of the insulation layer 14. In this case, the upper surface of the connection pads 15P is located below the upper surface of the insulation layer 14.

The covered surface 15A of the connection pad 15P may be rough. In an example, the covered surface 15A may have a greater surface roughness than the exposed surface 15B.

In the embodiment, in a cross-sectional view, the exposed surface 15B of the connection pad 15P is inclined straight. Alternatively, for example, the exposed surface 15B of the connection pad 15P may be curved.

In the embodiment, the lower surface of the connection pad 15P is curved. Alternatively, for example, the lower surface of the connection pad 15P may be horizontally flat in the planar direction.

In the embodiment, the recess 15X is arranged in the lower surface of the connection pad 15P. However, for example, the recess 15X may be omitted from the lower surface of the connection pad 15P.

In the embodiment, the structure of the connection terminal 30 may be changed. In an example, the structure of the connection terminal 30 may be changed so that the metal layer 31, which is a Ni layer, and the metal layer 33, which is a Au layer, are sequentially stacked.

In the embodiment, the insulation layers 12 and 14 may include a photosensitive resin as a main component. In this case, the material of the insulation layers 12 and 14 may be, for example, a photosensitive insulating resin including a phenol resin, a polyimide resin, or the like, as a main component.

In the embodiment, the number of wiring layers 11, 13, and 15, the number of insulation layers 12 and 14, and the layout of wirings in the wiring substrate 10 may be changed in various manners.

In the embodiment, the solder resist layer 16 may be omitted.

In the embodiment, the semiconductor element 41 is mounted on the wiring substrate 10. Alternatively, for example, instead of the semiconductor element 41, a chip component such as a chip capacitor, a chip resistor, or a chip inductor, or an electronic component such as a crystal oscillator may be mounted on the wiring substrate 10.

In the embodiment, the underfill resin 45 may be omitted.

In the embodiment, the structural body corresponding to the wiring substrate 10 is formed on only the lower surface of the support 50. Alternatively, for example, the structural body corresponding to the wiring substrate 10 may be formed on both the upper surface and the lower surface of the support 50.

In the above embodiment, the adhesion-promoting film 20 covers the lower surface of the metal film 53. Alternatively, for example, the adhesion-promoting film 20 may cover only the side surface of the metal layer 54 and the lower surface and the side surface of the connection pad 15P.

In the embodiment, the structure of the support 50 may be changed.

### Clauses

This disclosure further encompasses the following embodiments.

1. A method for manufacturing a wiring substrate, the method including:
preparing a support;
forming a connection pad on a lower surface of the support;
forming an adhesion-promoting film covering a lower surface and a side surface of the connection pad;
forming an insulation layer on a lower surface of the support so that the insulation layer includes a recess that accommodates the connection pad covered by the adhesion-promoting film;
forming a wiring layer on a lower surface of the insulation layer so that the wiring layer is electrically connected to the connection pad;
removing the support;
thinning the insulation layer and the adhesion-promoting film from an upper surface of the adhesion-promoting film so that an upper portion of the connection pad protrudes upward beyond an upper surface of the insulation layer; and
etching a portion of the connection pad, thereby forming a first gap between the side surface of the connection pad and a wall surface of the recess,
in which the forming a first gap includes etching a portion of the connection pad so that a portion of the side surface of the connection pad is exposed from the adhesion-promoting film defining an exposed surface and so that the exposed surface is inclined so as to approach a planar center of the connection pad as the exposed surface extends toward an upper surface of the connection pad.

Various changes in form and details may be made to the examples above without departing from the spirit and scope of the claims and their equivalents. The examples are for the sake of description only, and not for purposes of limitation. Descriptions of features in each example are to be considered as being applicable to similar features or aspects in other examples. Suitable results may be achieved if sequences are performed in a different order, and/or if components in a described system, architecture, device, or circuit are combined differently, and/or replaced or supplemented by other components or their equivalents. The scope of the disclosure is not defined by the detailed description, but by the claims and their equivalents. All variations within the scope of the claims and their equivalents are included in the disclosure.

What is claimed is:

1. A wiring substrate, comprising:
an insulation layer;
a recess recessed downward from an upper surface of the insulation layer;
a connection pad arranged in the recess;
an adhesion-promoting film arranged between a portion of a side surface of the connection pad and a portion of a wall surface of the recess so that the side surface of the connection pad includes
a covered surface covered by the adhesion-promoting film and
an exposed surface exposed from the adhesion-promoting film;
a first gap defined between the exposed surface of the connection pad and the wall surface of the recess;
a connection terminal covering an upper surface of the connection pad and filling the first gap; and
a wiring layer arranged on a lower surface of the insulation layer and electrically connected to the connection pad, wherein
the exposed surface is arranged above the covered surface, and
the exposed surface is inclined so as to approach a planar center of the connection pad as the exposed surface extends toward the upper surface of the connection pad.

2. The wiring substrate according to claim 1, wherein the adhesion-promoting film continuously covers the covered surface and a lower surface of the connection pad.

3. The wiring substrate according to claim 1, wherein
the first gap has a depth dimension in a depth direction and a width dimension in a width direction orthogonal to the depth direction, and
the depth dimension is smaller than the width dimension.

4. The wiring substrate according to claim 1, wherein the adhesion-promoting film covers a portion of the wall surface of the recess facing the exposed surface.

5. The wiring substrate according to claim 1, wherein
the side surface of the connection pad includes a first surface inclined outwardly downward from the upper surface of the connection pad and a second surface bent from the first surface and parallel to the wall surface of the recess,
the exposed surface is defined by an entirety of the first surface, and
the covered surface is defined by an entirety of the second surface.

6. The wiring substrate according to claim 1, wherein
the side surface of the connection pad includes a first surface inclined outwardly downward from the upper surface of the connection pad and a second surface bent from the first surface and parallel to the wall surface of the recess,
the exposed surface is defined by an entirety of the first surface and an upper portion of the second surface, and
the covered surface is defined by a lower portion of the second surface.

7. The wiring substrate according to claim 1, wherein the connection pad includes an upper portion protruding upward beyond the upper surface of the insulation layer.

8. The wiring substrate according to claim 1, wherein the connection pad includes an upper portion located below the upper surface of the insulation layer.

9. The wiring substrate according to claim 1, wherein the connection pad includes a lower surface curved downward toward the planar center of the connection pad.

10. The wiring substrate according to claim 1, wherein
a lower surface of the connection pad includes a recess that is recessed upward from the lower surface of the connection pad, and
the recess of the connection pad includes a surface that is curved upward toward a planar center of the recess.

11. The wiring substrate according to claim 1, wherein
the connection terminal has a structure in which a first metal layer and a second metal layer are sequentially stacked,
the first metal layer covers an entirety of the upper surface of the connection pad and an entirety of the exposed surface and fills the first gap, and
the second metal layer covers a surface of the first metal layer.

12. The wiring substrate according to claim 11, wherein the connection terminal includes a third metal layer formed on the second metal layer.

13. A semiconductor device, comprising:
the wiring substrate according to claim 1; and
a semiconductor element being flip-chip-mounted on the connection terminal.
